(19) United States
(12) Patent Application Publication
(10) Pub. No.: US 2026/0095681 A1
(43) Pub. Date: Apr. 2, 2026

(54) EMBEDDED MEMORY IN MACROPIXEL OF PHOTODIODE-BASED SENSOR ARRAY

(71) Applicant: STMicroelectronics International N.V., Geneva (CH)

(72) Inventors: Neale DUTTON, Edinburgh (GB); Robert HENDERSON, Edinburgh (GB)

(21) Appl. No.: 18/901,732

(22) Filed: Sep. 30, 2024

(51) Int. Cl. H04N 25/767; G11C 11/419; H04N 25/42; H04N 25/705; H10B 10/00

(52) U.S. Cl. CPC H04N 25/767; G11C 11/419; H04N 25/42; H04N 25/705; H10B 10/12

(57) ABSTRACT

An example macropixel, an image sensor comprising a plurality of macropixels, a high resolution scanner based on an array of macropixels, and a time delay integration sensor utilizing an array macropixels are provided. The example macropixel includes photodiodes, memory devices, and switching circuitry configured to switch between a high dynamic range image capture mode and a time-of-flight sensing mode. The memory devices, include at least one memory device for each photodiode in the plurality of photodiodes. During the high dynamic range image capture mode, a corresponding memory device is configured to determine an individual intensity of light received at a particular photodiode. During the time-of-flight sensing mode, each memory device is configured to determine an intensity of light received at a group of photodiodes during a time period, wherein each memory device is associated with a different time period.

### TECHNOLOGICAL FIELD

Embodiments of the present disclosure relate generally to photodiode-based sensor arrays, and more particularly, to photodiode-based sensor arrays comprising macropixels having embedded memory.

### BACKGROUND

A sensing device may utilize a plurality of photodiode pixels, arranged in an array for a variety of sensing applications. For example, photodiode pixels may be utilized to generate high dynamic range (HDR) images by accumulating output voltage pulses at each photodiode pixel to determine the pixel intensity during an integration period. In addition, photodiode pixels may be utilized to determine time-of-flight in various sensor applications.

Applicant has identified many technical challenges and difficulties associated with photodiode pixels on sensing devices. Through applied effort, ingenuity, and innovation, Applicant has solved problems related to the use of photodiode pixels on a sensing device by developing solutions embodied in the present disclosure, which are described in detail below.

### BRIEF SUMMARY

Various embodiments are directed to an example macropixel, an image sensor comprising a plurality of macropixels, a high resolution scanner based on an array of macropixels, and a time delay integration sensor utilizing an array macropixels.

An example macropixel is provided. The example macropixel comprises a plurality of photodiodes, a plurality of memory devices, and switching circuitry configured to switch between a high dynamic range image capture mode and a time-of-flight sensing mode. The plurality of memory devices, comprising at least one memory device for each photodiode in the plurality of photodiodes. During the high dynamic range image capture mode, a corresponding memory device of the plurality of memory devices is configured to determine an individual intensity of light received at a particular photodiode of the plurality of photodiodes. During the time-of-flight sensing mode, each memory device of the plurality of memory devices is configured to determine a group intensity of light received at the plurality of photodiodes during a time period, wherein each memory device is associated with a different time period.

In some embodiments, the macropixel further comprises front end circuitry for each photodiode in the plurality of photodiodes. The front end circuitry comprising a flip-flop configured to receive a pixel clock and an electrical output of a corresponding photodiode in the plurality of photodiodes, the electrical output corresponding to the individual intensity of light received at the photodiode. The flip-flop is configured to capture a digital photon indicator based on the electrical output at a cycle of the pixel clock. The digital photon indicator indicates reception of one or more photons at the photodiode.

In some embodiments, the macropixel further comprises shift register circuitry configured to transmit the digital photon indicator between each flip-flop of the front end circuitry based on the pixel clock.

In some embodiments, the front end circuitry further comprising a mux configured to select between the electrical output of the corresponding photodiode and the digital photon indicator from a neighboring flip-flop.

In some embodiments, during the high dynamic range image capture mode, the mux is configured to select the electrical output of the corresponding photodiode.

In some embodiments, during the time-of-flight sensing mode, the mux is configured to select the digital photon indicator from the neighboring flip-flop.

In some embodiments, the switching circuitry is configured to receive the electrical output from each photodiode in the plurality of photodiodes to generate a combined electrical output.

In some embodiments, the switching circuitry is configured to transmit the combined electrical output to a first flip-flop in the plurality of flip-flops, wherein the first flip-flop is included in the shift register circuitry.

In some embodiments, during the high dynamic range image capture mode the corresponding memory device stores a count representing the intensity of light received at the particular photodiode.

In some embodiments, each memory device of the plurality of memory devices comprises static random access memory (SRAM) defined by one or more SRAM bits.

In some embodiments, each SRAM bit comprises a six transistor SRAM component.

In some embodiments, each memory device of the plurality of memory devices comprises at least sixteen SRAM bits.

In some embodiments, the macropixel comprise two or more memory devices for each photodiode, wherein a first memory device stores a first intensity of light during a first frame and a second memory device stores a second intensity of light during a second frame.

In some embodiments, each photodiode in the plurality of photodiodes comprises an avalanche photodiode.

In some embodiments, the macropixel comprises a top layer comprising the plurality of photodiodes; and a bottom layer comprising the plurality of memory devices and the switching circuitry.

In some embodiments, the macropixel further comprises a bidirectional data interface enabling data writes to the plurality of memory devices and data reads from the plurality of memory devices.

In some embodiments, the macropixel further comprises arithmetic logic circuitry configured to perform arithmetic operations in combination with data writes and data reads.

An image sensor comprising a plurality of macropixels arranged in a two-dimensional macropixel array comprising rows and columns is further provided. In some embodiments, each macropixel comprises: a plurality of photodiodes; a plurality of memory devices; switching circuitry; and a bidirectional data interface enabling data writes to the plurality of memory devices and data reads from the plurality of memory devices. The plurality of memory devices, comprising at least one memory device for each photodiode in the plurality of photodiodes. The switching circuitry configured to switch between a high dynamic range image capture mode and a time-of-flight sensing mode. During the high dynamic range image capture mode, a corresponding memory device of the plurality of memory devices is configured to determine an intensity of light received at a particular photodiode of the plurality of photodiodes. During the time-of-flight sensing mode, each memory device of the plurality of memory devices is configured to determine an intensity of light received at the plurality of photodiodes during a time period, wherein each memory device is associated with a different time period.

In some embodiments, the image sensor further comprises bidirectional read-write circuitry configured to interface with each of the bidirectional data interfaces.

In some embodiments, the image sensor further comprises column parallel processing circuitry electrically connected to the bidirectional read-write circuitry and configured to perform image processing operations on image data stored in one or more macropixel memory devices.

In some embodiments, the image processing operations include at least one of peak finding operations, centroiding operations, edge detection operations and movement operations.

In some embodiments, each macropixel further comprises two or more memory devices for each photodiode.

In some embodiments, a first memory device of the two or more memory devices stores an intensity of light associated with a corresponding photodiode, and a second memory device stores a weight associated with a machine learning model.

In some embodiments, the image processor further comprises a neural network processing engine configured to perform one or more machine learning operations.

In some embodiments, the neural network processing engine is configured to apply the weight stored in the second memory device to the intensity of light stored in the first memory device.

In some embodiments, the neural network processing engine is further configured to determine a classification based on the machine learning model.

In some embodiments, the classification is transmitted to a device external to the image sensor while intensity data remains on the image sensor.

A high resolution scanner is further provided. The high resolution scanner comprising an illumination source configured to generate a light blade; an image sensor; and a controller electrically connected to the illumination source and the image sensor. The image sensor positioned to receive reflected light from the light blade, the image sensor comprising a plurality of macropixels arranged in a two-dimensional macropixel array comprising rows and columns, each macropixel comprising: a plurality of photodiodes; a plurality of memory devices; switching circuitry configured to switch between a high dynamic range image capture mode and a time-of-flight sensing mode; and a bidirectional data interface. The plurality of memory devices, comprising at least one memory device for each photodiode in the plurality of photodiodes. The bidirectional data interface enabling data writes to the plurality of memory devices and data reads from the plurality of memory devices. During the high dynamic range image capture mode, a corresponding memory device of the plurality of memory devices is configured to determine an intensity of light received at a particular photodiode of the plurality of photodiodes. During the time-of-flight sensing mode, each memory device of the plurality of memory devices is configured to determine an intensity of light received at the plurality of photodiodes during a time period, wherein each memory device is associated with a different time period.

In some embodiments, the image sensor further comprising bidirectional read-write circuitry configured to interface with each of the bidirectional data interfaces.

In some embodiments, the controller is configured to: determine one or more active rows of macropixels, wherein the one or more active rows are within a range of the reflected light from the light blade; receive a first light intensity for an illuminated macropixel in the one or more active rows, wherein the first light intensity corresponds to reflected light received at the plurality of photodiodes comprising the illuminated macropixel during a first time period; write the first light intensity to a first memory device associated with a first macropixel, the first macropixel in the same column as the illuminated macropixel; receive a second light intensity for the illuminated macropixel, wherein the second light intensity corresponds to reflected light received at the plurality of photodiodes comprising the illuminated macropixel during a second time period; and write the second light intensity to a second memory device associated with a second macropixel, the second macropixel in the same column as the illuminated macropixel.

In some embodiments, the first macropixel and the second macropixel are different macropixels.

In some embodiments, each memory device of each macropixel in the same row as the illuminated macropixel represents a light intensity received at the illuminated macropixel during the different time period.

A time delay integration sensor is further provided. The time delay integration sensor comprising an illumination source configured to transmit a light blade toward a moving object; an image sensor positioned to receive reflected light from the light blade; and a controller electrically connected to the illumination source and the image sensor. The image comprising a plurality of macropixels arranged in a two-dimensional macropixel array comprising rows and columns, each macropixel comprising: a plurality of photodiodes; a plurality of memory devices, comprising at least one memory device for each photodiode in the plurality of photodiodes; switching circuitry; and a bidirectional data interface. The switching circuitry configured to switch between a high dynamic range image capture mode and a time-of-flight sensing mode. The bidirectional data interface enabling data writes to the plurality of memory devices and data reads from the plurality of memory devices. During the high dynamic range image capture mode, a corresponding memory device of the plurality of memory devices is configured to determine an intensity of light received at a particular photodiode of the plurality of photodiodes. During the time-of-flight sensing mode, each memory device of the plurality of memory devices is configured to determine an intensity of light received at the plurality of photodiodes during a time period, wherein each memory device is associated with a different time period.

In some embodiments, the image sensor further comprising shift register circuitry configured to shift an electrical output from one or more of the plurality of photodiodes to a flip-flop device electrically connected to each memory device of the plurality of memory devices, based on a movement of a moving target object.

In some embodiments, the shift register circuitry is further configured to transmit the electrical output to a neighbor macropixel in a same column of the two-dimensional macropixel array.

In some embodiments, the electrical output is written to a memory device of the plurality of memory devices within each macropixel in the same column of the two-dimensional macropixel array based on a position of the moving object relative to the image sensor.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates an example macropixel array in accordance with an example embodiment of the present disclosure.

FIG. 2 illustrates a block diagram of an example macropixel in accordance with an example embodiment of the present disclosure.

FIG. 3 illustrates a block diagram of an example macropixel in accordance with an example embodiment of the present disclosure.

FIG. 4 depicts an example embodiment of a macropixel in accordance with an example embodiment of the present disclosure.

FIG. 5 illustrates an example macropixel operating in a high dynamic range image capture mode in accordance with an example embodiment of the present disclosure.

FIG. 6 illustrates an example macropixel operating in a time-of-flight sensing mode in accordance with an example embodiment of the present disclosure.

FIG. 7 illustrates a block diagram of an example macropixel including interface circuitry in accordance with an example embodiment of the present disclosure.

FIG. 8 depicts an example embodiment of a macropixel comprising interface circuitry in accordance with an example embodiment of the present disclosure.

FIG. 9 depicts an example image sensor comprising a macropixel array in accordance with an example embodiment of the present disclosure.

FIG. 10 illustrates an example image sensor comprising a macropixel array and a neural network processing engine in accordance with an example embodiment of the present disclosure.

FIG. 11 illustrates a block diagram of an example high resolution scanner in accordance with an example embodiment of the present disclosure.

FIG. 12A-FIG. 12C illustrate example operation of an example high resolution scanner in accordance with an example embodiment of the present disclosure.

FIG. 13 illustrates an example block diagram of an example time delay integration sensor in accordance with an example embodiment of the present disclosure.

FIG. 14 illustrates an example block diagram of a macropixel array performing a circular shift in accordance with an example embodiment of the present disclosure.

FIG. 15 illustrates an example process for writing memory devices on an example high resolution scanner in accordance with an example embodiment of the present disclosure.

FIG. 16 depicts a block diagram of example components of a controller in accordance with an example embodiment of the present disclosure.

### DETAILED DESCRIPTION

Example embodiments will be described more fully hereinafter with reference to the accompanying drawings, in which some, but not all embodiments of the inventions of the disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

Various example embodiments address technical problems associated with area, performance, and efficiency issues related to pixel circuitry of a photodiode-based sensor on a sensing device. As understood by those of skill in the field to which the present disclosure pertains, there are numerous example scenarios in which a device, system, or application may benefit from decreased area and/or increased performance and efficiency of photodiode circuitry on a sensing device.

In general, a sensing device may comprise a photodiode-based sensor configured to utilize a plurality of photodiode pixels, arranged in an array, to capture light intensity data from a surrounding environment. Light intensity data from a surrounding environment may be used for a variety of sensing applications. For example, photodiode pixels may accumulate output voltage pulses at each photodiode pixel to determine the pixel intensity during an integration period and generate high dynamic range images. In addition, photodiode pixels may be utilized to determine time-of-flight of a reflected light output in various sensor applications.

Many sensing devices utilize single-photon avalanche diodes (SPAD) as the photodetection device in a photodiode pixel. A SPAD is a solid state photodetector that in general utilizes a p-n junction to form a diode to enable the flow of current in an instance in which a particle of electromagnetic energy, such as a photon, encounters the p-n junction. A photodiode pixel utilizing a SPAD is designed such that the absorption of even a single photon can cause impact ionization, causing an avalanche current to develop. The voltage generated by the impact ionization creates a voltage pulse at the output of a SPAD-based photodiode pixel. The output voltage pulse generated by the SPAD-based photodiode pixel may be used to detect the arrival of photons and determine a precise timing of arrival. SPAD-based photodiode pixels are particularly useful in low-light applications.

Photodiode-based sensors may have certain limitations. For example, photodiode-based sensors are bottom die limited as the photodiodes are generally on both layers of the sensor substrate. Thus, memory devices utilized as computational frame stores have traditionally been placed outside the photodiode array or separate from the photodiode-based sensor. Positioning memory devices outside of the photodiode array increases the silicon area required for a sensing device. In addition, exporting sensor data to external memory devices involves significant power consumption and data bandwidth penalties related to the transfer of large amounts of image data over external interfaces to a frame store external memory device. Problems related to increased silicon area, power consumption, and data bandwidth penalties continue to be magnified as photodiode-based sensing devices scale to higher resolutions.

The various example embodiments described herein utilize various techniques to reduce the area occupied by a photodiode-based sensor of a sensing device. In addition, significant benefits in the functionality and performance of a photodiode-based sensor may be realized based on the herein described techniques.

For example, a sensing device utilizing a photodiode-based sensor in accordance with the present device utilizes a two-dimensional array of macropixels to detect light. A macropixel includes a plurality of photodiodes and corresponding circuitry. The circuitry at each macropixel includes at least front end circuitry associated with each photodiode, and at least one memory device (e.g., memory word) associated with each photodiode. In some embodiments, a photodiode-based sensor includes two layers. The macropixel may be configured such that a top layer includes the plurality of photodiodes exposed to an external environment, and a bottom layer includes the front end circuitry, and the memory words. By including a memory word for each photodiode at the macropixel location, there is no need to transmit the photodiode output to an external memory outside of the array of macropixels to capture the photodiode state. Positioning memory devices under the photodiode layer significantly reduces the area required by a pixel array of a sensing device relative to an alternative digital scheme whereby counters composed of D-type flip-flops are used to count state. In other examples, analog devices may be employed to reduce pixel area. However, analog devices are associated with leakage and variability issues and cannot be easily re-purposed for computation or storage, as is possible with digital circuits.

In addition, the macropixel architecture of the present disclosure provides additional functionality. In some embodiments, each macropixel may additionally include shift register circuitry and a switching device at the macropixel location on the circuitry layer beneath the photodiodes. The switching device enables switching of the capture mechanism of the macropixel between an HDR image capture mode and a time-of-flight sensing mode. During an HDR image capture mode the light intensity during an integration period for each individual photodiode is captured at a dedicated memory word. The size of the memory word dictates the resolution of each macropixel of the photodiode-based array. During a time-of-flight sensing mode, the shift register circuitry is enabled such that each memory word of the macropixel is configured to receive light intensity data corresponding to light received during a different time period at the plurality of photodiodes comprising the macropixel.

In some embodiments, two or more memory words may be associated with each photodiode of the macropixel. Two or more memory words may enable the storage of multiple images when operating in a high dynamic range image capture mode. In a time-of-flight sensing mode, two or more memory words may increase the range and/or resolution of the time-of-flight sensor.

In some embodiments, each macropixel further includes a bidirectional data interface. The bidirectional data interface enables direct read and write operations to and from each memory word of the memory device of the macropixel. Such a bidirectional data interface enables direct interface with external devices, or local computational sources placed in a column parallel fashion at the exterior of the pixel array. External device may include computational resources, such as CPUs, GPUs, neural nets, and so on. As such, the memory words within the pixel array may be used initially for image capture and then subsequently for image processing in a time-interleaved fashion. Such processing may be performed without exporting the full image information to an external resource or memory device with a separate frame store. In addition, each macropixel may further include arithmetic logic circuitry. Along with the bidirectional data interface, the arithmetic logic circuitry enables basic arithmetic operations to be performed on the data contained in each memory word of the memory device of the macropixel.

In some embodiments, a photodiode-based sensor according to the present disclosure may include a plurality of macropixels arranged in a two-dimensional macropixel array. The two-dimensional macropixel array may further include bidirectional read-write circuitry configured to interface with the bidirectional data interface at each macropixel. Utilizing column parallel processing circuitry connected to the bidirectional read-write circuitry, various operations may be performed at the photodiode-based sensor level of the sensing device. For example, image processing operations such as peak finding operations, centroiding operations, edge detection operations, and movement operations may be performed at the macropixel level, before transmitting the stored data off the photodiode-based sensor. In addition, in some embodiments, a neural network processing engine may read and write directly to the memory words of the macropixels on a photodiode-based sensor. By writing weights or other hyperparameters to the memory words of a macropixel, neural network operations may be performed more efficiently.

Utilizing the operations enabled by the column parallel processing circuitry in conjunction with the bidirectional read-write circuitry the functionality of various sensing devices may be improved. For example, high resolution scanners may utilize the various memory words of inactive macropixels in the macropixel array to increase the resolution of the scanner. Further, time delay integration sensors may utilize circular shifts between memory words of macropixels within a column to provide higher resolution images of objects moving rapidly by the time delay integration sensor.

As a result of the herein described example embodiments, the functionality of a photodiode-based sensor on a sensing device may be greatly enhanced. In addition, by providing a memory device at each photodiode of a photodiode-based sensor, the size required by a photodiode-based sensor may be greatly reduced.

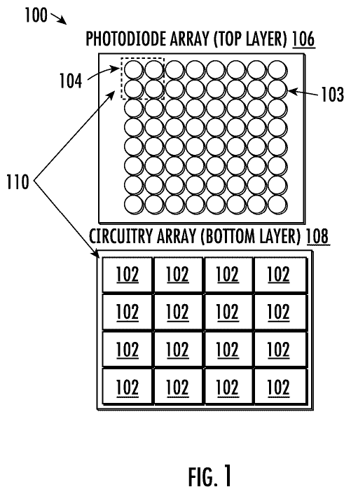

Referring now to FIG. 1, an example macropixel array 100 of a photodiode-based sensor is provided. As depicted in FIG. 1, the example macropixel array 100 includes two layers, a top layer 106 comprising a photodiode array and a bottom layer 108 comprising a circuitry array. The photodiode array includes an array of photodiodes 103 with a plurality of adjacent photodiodes 103 grouped in a photodiode group 104. The circuitry array includes macropixel circuitry 102 for an associated photodiode group 104. The photodiode group 104 on the top layer 106 and corresponding macropixel circuitry 102 on the bottom layer 108 together comprise a macropixel 110. By stacking the photodiode group 104 on top of the associated macropixel circuitry 102, the macropixel 110 and thus the macropixel array 100 occupy less area.

As depicted in FIG. 1, the photodiodes 103 are arranged in a two-dimensional array of rows and columns on the top layer 106. A photodiode 103 is any device, avalanche photodiode, SPAD, or other structure that produces an electric current corresponding to the light received at the photodiode 103. A photodiode 103 may comprise an array of photodiodes 103, each configured to convert photons into an electric current. In some embodiments, a photodiode 103 may comprise a SPAD. A SPAD is a solid state photodetector that utilizes a p-n junction to form a diode to enable the flow of current in an instance in which a particle of electromagnetic energy, such as a photon, encounters the SPAD. A SPAD is reverse biased with a SPAD bias voltage higher than a breakdown voltage of the SPAD and devoid of charge carriers, creating a high electric field. Due to the high electric field, in an instance in which a photon hits the SPAD 116 an avalanche condition (e.g., impact ionization) is triggered. The avalanche condition generates a short, high current pulse on the photon detection signal.

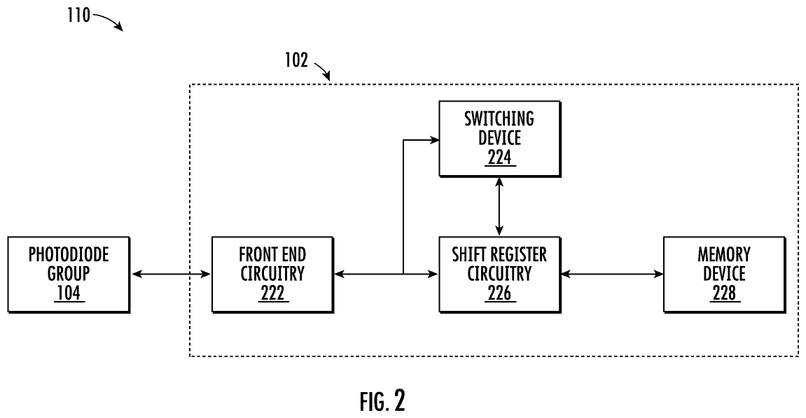

As further depicted in FIG. 1, a plurality of adjacent photodiodes 103 are grouped in a photodiode group 104. A photodiode group 104 may comprise any number of adjacent photodiodes 103. As further described in relation to FIG. 2, a photodiode group 104 may be included in a macropixel 110 and may share certain components of the macropixel circuitry 102. As described herein, a macropixel 110 comprises macropixel circuitry 102 and the associated photodiode group 104. Thus, a macropixel 110 includes a plurality of photodiodes 103.

Referring now to FIG. 2, a block diagram of an example macropixel 110 including example macropixel circuitry 102 is provided. As depicted in FIG. 2, the example macropixel 110 includes a photodiode group 104 electrically connected to macropixel circuitry 102. The example macropixel circuitry 102 includes front end circuitry 222 electrically connected to the photodiode group 104, shift register circuitry 226, and a switching device 224. The switching device 224 is further electrically connected to the shift register circuitry 226. As further depicted in FIG. 2, the memory device 228 is electrically connected to the shift register circuitry 226.

As depicted in FIG. 2, the macropixel circuitry 102 includes front end circuitry 222. Every photodiode in the photodiode group 104 includes front end circuitry 222. For description purposes, the photodiode of the photodiode group 104 paired with the front end circuitry 222 may be referred to as the corresponding photodiode. The front end circuitry 222 comprises hardware components, including switching devices, transistors, registers, flip-flops, etc., configured to generate an electrical output based on the intensity of light received at the corresponding photodiode. In an instance in which the corresponding photodiode is a SPAD, the front end circuitry 222 may include various electrical components configured to modify the output signal in an instance in which a single photon is received. For example, in some embodiments, the discharge of the SPAD may indicate receipt of a photon at the SPAD. In some embodiments, an output pulse may indicate receipt of a photon at the SPAD. Electrical components configured to generate an output signal in an instance in which a photon is received may include quenching circuitry, clamping circuitry, voltage dividers, recharge circuitry, and so on.

The front end circuitry 222 may further include a register device. A register device may be any hardware component configured to hold a digital state. For example, a register device may include a flip-flop, latch, or other device configured to store a digital state. A register device may be configured to receive a clock signal. In some embodiments, the register device may register the output of the corresponding photodiode and associated circuitry based on a change of state of the clock signal (e.g., rising edge and/or falling edge of the clock). Thus, a digital value is stored by the register device based on the output of the corresponding photodiode. In some embodiments, a digital zero may be stored by the register device in an instance in which one or more photons are received at the corresponding photodiode during the clock cycle.

The front end circuitry 222 may further include one or more electrical components configured to control the write of the digital state registered by the register device into the memory word associated with the corresponding photodiode. For example, in some embodiments, an access signal may control the write of the register device state into the corresponding memory device.

In addition, in some embodiments, multiple memory words may be associated with a single corresponding photodiode of the photodiode group 104. For example, in an image capture mode, a first frame captured during a first integration period may be recorded in a first memory word and a second frame captured during a second integration period may be recorded in a second memory word. The front end circuitry 222 may include circuitry enabling a memory word based on the integration period. Such functionality enables the store of multiple image frames directly on the photodiode-based sensor.

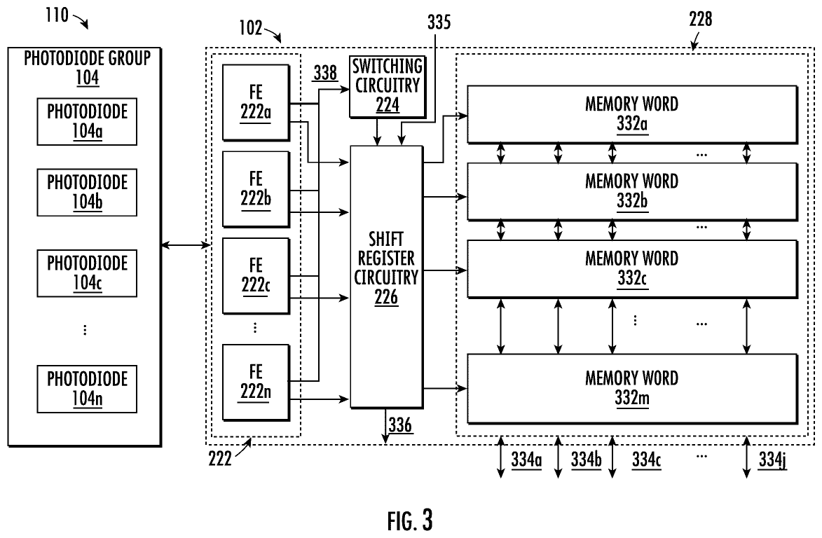

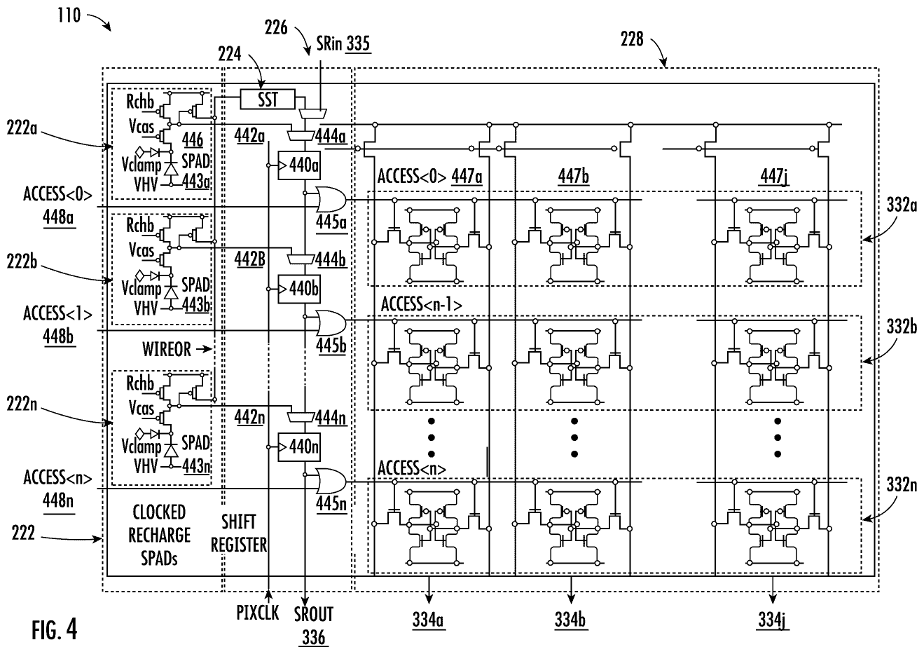

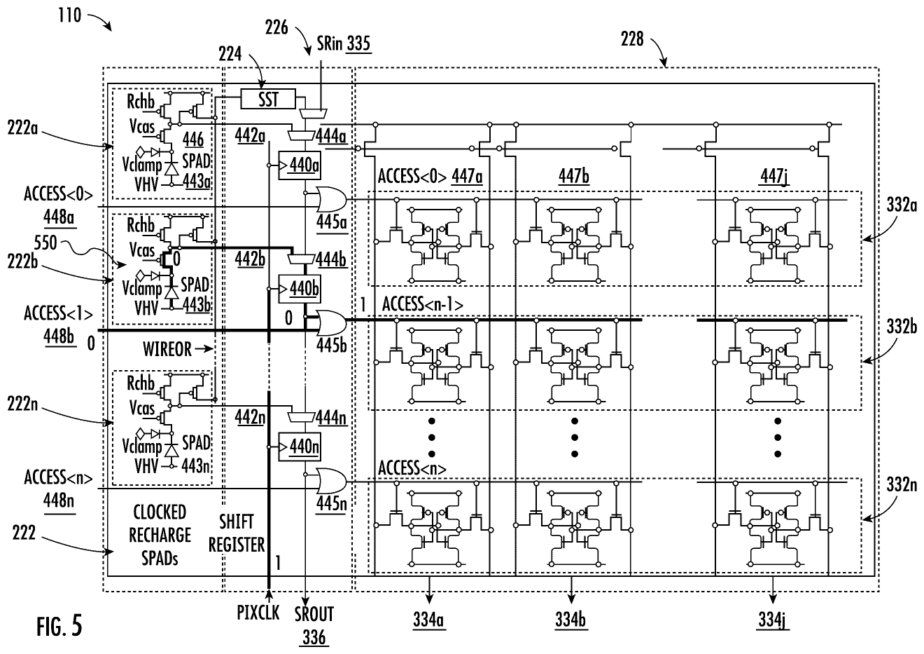

As further depicted in FIG. 2, the macropixel circuitry 102 may include a switching device 224. The switching device 224 comprises hardware components including muxes, switches, registers, and the like, configured to transition the macropixel circuitry 102 from a high dynamic range image capture mode to a time-of-flight sensing mode, and vice versa. The high dynamic range image capture mode and the time-of-flight sensing mode are further described in relation to FIG. 3, FIG. 4, and FIG. 5.

As further depicted in FIG. 2, the macropixel circuitry 102 includes shift register circuitry 226. The shift register circuitry 226 comprises hardware components including but not limited to muxes and registers, configured to synchronously shift data bits through a series of register devices based on a clock cycle. For example, shift register circuitry 226 comprising register devices (1, 2, 3, 4, etc. ,) connected in sequence may shift a data bit to the next register device in the sequence on each clock cycle. In an instance in which a logic 1 is written to the first register device on during a first clock period, the logic 1 is stored at the second register device during the second clock period, at the third register device during the third clock period, and so on. Thus, the position of a register device in the shift register circuitry 226 represents a passage of time since the value was written to the first register device.

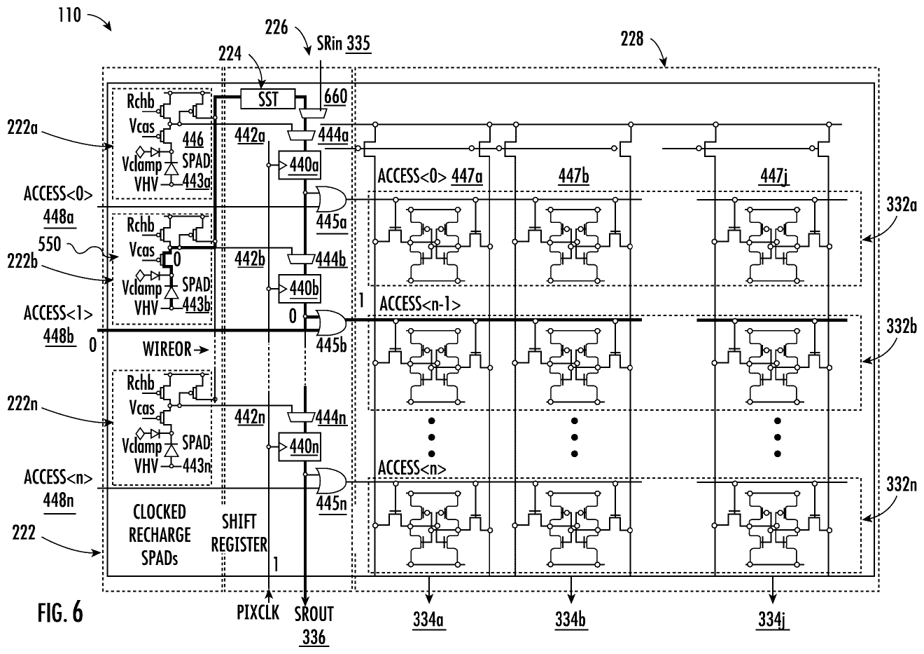

The shift register circuitry 226 of the macropixel circuitry 102 may be configured to shift a combined electrical output through the shift register circuitry 226. The combined electrical output may comprise the electrical output from each of the photodiodes comprising the photodiode group 104 of the macropixel 110. The combined electrical output may be combined onto a single conductive path. Thus, one or more photons received at any of the photodiodes in the photodiode group 104 is indicated on the combined electrical output. The combined electrical output may then be transmitted to the first register device in the shift register circuitry 226 and stored as a digital value (e.g., digital photon indicator) in the first register device. The digital value may then be shifted through the shift register circuitry 226 at each successive clock cycle. Thus, the digital value at the end of the shift register circuitry 226 represents light received at the photodiode group 104 during a first time period and the digital value at the beginning of the shift register circuitry 226 represents light received at the photodiode group 104 during a last time period. Such operation of the shift register circuitry 226 may enable time-of-flight sensing as further described in relation to FIG. 3 and FIG. 6.

In some embodiments, the shift register circuitry 226 may share components of the front end circuitry 222. For example, the shift register circuitry 226 may utilize one or more register devices utilized to capture the electrical output of the front end circuitry 222 as the register device stages of the shift register circuitry 226.

As further depicted in FIG. 2, the macropixel circuitry 102 may include a memory device 228. A memory device 228 comprises any electrical components configured to store a digital value and further configured to be positioned on a bottom layer of the macropixel circuitry 102 under the top layer comprising the photodiode group 104 and in close proximity to the photodiode group 104 in the macropixel 110. A memory device 228 may be configured to store a count representing light intensity received at one or more photodiodes of the photodiode group 104 during a time period. A memory device 228 may comprise any volatile or non-volatile memory device. For example, the memory device 228 may comprise static random access memory (SRAM). SRAM comprises the necessary fast read/write times and non-volatility necessary for use in the macropixel circuitry 102. As further described herein, the memory device 228 comprises a plurality of memory words based on the number of photodiodes in the photodiode group 104, each memory word comprising a number of memory bits determining the resolution of the light intensity count. The memory device 228 is further described in relation to FIG. 2.

Referring now to FIG. 3, an example block diagram of various components of the macropixel 110 is provided. As depicted in FIG. 3, the macropixel 110 includes a photodiode group 104 comprising a plurality of photodiodes 104a-104n electrically connected to macropixel circuitry 102. The example macropixel circuitry 102 includes front end circuitry 222 electrically connected to the photodiode group 104, shift register circuitry 226, and the switching device 224. The switching device 224 is further electrically connected to the shift register circuitry 226. The memory device 228 is electrically connected to the shift register circuitry 226. As further depicted in FIG. 3, the front end circuitry 222 comprises a plurality of front end circuitries 222a-222n, one front end circuitry 222a-222n for each photodiode 104a-104n in the photodiode group 104 comprising the macropixel 110. In addition, the memory device 228 includes a plurality of memory words 332a-332m, at least one memory word 332a-332m for every photodiode 104a-104n of the photodiode group 104 of the macropixel 110. As further depicted in FIG. 3, read-write data lines 334a-334j are output from the memory device 228. Further, a shift register input 335 and shift register output 336 provide external interfaces to the shift register circuitry 226 of the macropixel 110.

As depicted in FIG. 3, the example macropixel 110 includes a photodiode group 104 comprising a plurality of photodiodes 104a-104n and a plurality of front end circuitries 222a-222n corresponding to the plurality of photodiodes. Each photodiode 104a-104n is associated with a front end circuitry 222a-222n providing an interface with the memory device 228, for example, in a high dynamic range image capture mode, and an interface with the switching device 224/shift register circuitry 226 in a time-of-flight sensing mode.

As further depicted in FIG. 3, the memory device 228 comprises a plurality of memory words 332a-332m. A memory word 332a-332m is a single memory location comprising a plurality of memory bits (e.g., j memory bits), each memory bit configured to store a digital logic value (e.g., 0, 1). Thus, a memory bit may comprise any hardware component configured to store two states, for example a register, SRAM (e.g., SRAM bits), dynamic random access memory (DRAM), a latch, or another state saving device. The number of memory bits may correspond to the resolution of a captured image. For example, a word comprising 16 bits may store 65,536 unique values, enabling a count from 0-65535. As such, the intensity of each macropixel may range from 0-65535. The number of memory bits may be related to the typical full well capacity of pinned photodiode pixels, for example, 10,000 electrons or so. Thus, in some embodiments, each memory word 332a-332n may include 10 or more memory bits; more preferably 12 or more memory bits; most preferably 16 or more memory bits. With more memory bits, saturation and/or clipping at the macropixel 110 is less likely to occur, increasing the dynamic range of the imaging device.

In some embodiments, the memory device 228 may comprise two or more memory words 332a-332n per photodiode 104a-104n. In such an instance, successive image frames may be written in different memory words 332a-332n. For example, a first image frame may be written to a first memory word 332a-332n, a second image frame may be written to a second memory word 332a-332n, and so on. In an instance in which the photodiode group 104 includes 4 photodiodes, and the memory device 228 includes 8 memory words, the memory device 228 may store two frames for each photodiode in the on sensor memory device 228. In addition, additional memory words 332a-332n may increase the range and/or resolution of a time-of-flight sensing device when in time-of-flight sensing mode.

As further depicted in FIG. 3, read-write data lines 334a-334j may enable data to be transmitted and received directly at the memory words 332a-332n of the macropixel 110 memory device 228. Thus, an external device may access the data stored in each of the memory words 332a-332m. Further, an external device may write to any of the memory words 332a-332m comprising the memory device 228 of the macropixel 110. As such, the memory words 332a-332m may be written to by either the front end circuitry 222/shift register circuitry 226 comprising intensity data from the photodiode group 104, and/or by external devices through the read-write data lines 334a-334j.

Storage of memory frames within the memory device 228 of the macropixel 110 and read-write data channels 224a-334j to each of the memory words 332a-332n may enable certain operations, such as image processing operations, to be performed on the image data on the photodiode-based sensor without transmitting the data off the sensor.

As further depicted in FIG. 3, the switching device 224 may configure the macropixel circuitry 102 to operate in a high dynamic range image capture mode or a time-of-flight sensing mode.

During a high dynamic range image capture mode, a single photodiode (e.g., photodiode 104a) is associated with a corresponding memory word (e.g., memory word 332a) for the duration of an image frame integration period. In some embodiments, a count in the corresponding memory word of the memory device 228 is incremented based on the number of photons received at a single photodiode for the totality of an integration period. At the end of the integration period, the count in the memory word represents the intensity of light received at the photodiode during the integration period. In other words, the count in the memory word represents the intensity of one pixel during one image frame (e.g., integration period).

The integration period may be defined by various settings of a sensing device, including but not limited to frame rate, exposure time, ISO shutter speed, and so on. For example, in an instance in which a sensing device is configured to capture frames at a frame rate of 60 frames per second, the integration period may be at or near 1/60 second or 16.667 milliseconds. In some embodiments, the memory word count may be updated based on the frequency of the pixel clock at the front end circuitry 222, as well as any access signals required in the front end circuitry 222. As a non-limiting example, the register device may update on every pixel clock cycle in which a photon is received at the corresponding photodiode. In an instance in which the write to the memory word is enabled, the count in the memory word is incremented. The process continues until the integration period ends, at which time the count in the memory word is stored, transmitted, saved, or otherwise managed.

During a time-of-flight sensing mode the plurality of memory words 332a-332m in the memory device 228 are associated with a stage in the shift register circuitry 226. As described previously, data is shifted through the shift register circuitry 226 in synchronization with a pixel clock. Thus, the farther data is shifted in the shift register circuitry 226, the more time has passed since the data was captured. In the time-of-flight sensing mode the switching device 224 causes a combined electrical output 338 to be passed to the first register device in the shift register circuitry 226 at the end of the first time period. The combined electrical output 338 comprises the electrical output from each of the photodiodes 104a-104n in the photodiode group 104. As such, one or more photons received at any of the photodiodes 104a-104n in the photodiode group 104 is captured in the first register device of the shift register circuitry 226, indicating a photon was received by at least one of the photodiodes 104a-104n during the integration time.

During an example time-of-flight sensing mode, an illumination source may transmit a light pulse into an environment and a first integration time may start. During the first integration time, any photon received at any one of the photodiodes 104a-104n is reflected in the combined electrical output 338. At the end of the first integration time, the combined electrical output is captured in the first register device of the shift register circuitry 226, indicating whether one or more photons were received at any one of the photodiodes 104a-104n during the first integration time. An integration time may typically be on the order of nanoseconds, commensurate with the distance to be measured by the time-of-flight sensor. In conventional image capture mode, the integration time may typically be on the order of milliseconds.

Along with capturing the combined electrical output at the first register device, the second integration time is started. The digital value stored in the first register device is a digital photon indicator. At the end of the second integration time, the digital photon indicator stored in the first register device is shifted to the second register device and a second digital photon indicator corresponding to the second integration time is stored in the first register device. Similarly, at the end of the third integration time, the digital photon indicator stored in the second register device is shifted to the third register device; the digital photon indicator stored in the first register device is shifted to the second register device; and the digital photon indicator corresponding to the third integration time is stored in the first register device. Once the first digital photon indicator corresponding to the first integration time has moved to the end of the shift register circuitry 226, the value is used to increment the corresponding memory word 332a-332n. Thus, each memory word 332a-332n stores the count for a different distance from the sensing device based on the time-of-flight of the light pulse. For example, the memory word 332n may correspond to the closest range, for example, 1-3 meters. The next memory word may correspond to the next range, for example, 4-6 meters. The next memory word may correspond to the next range, for example, 7-10 meters, and so on, until the last memory word (e.g., memory word 332a) corresponds to the farthest range, for example, 20-30 meters.

Referring now to FIG. 4, an example embodiment of a macropixel 110 is provided. As depicted in FIG. 4, the macropixel 110 includes a photodiode group comprising a plurality of SPADs 443a-443n electrically connected to front end circuitry 222a-222n. The example front end circuitry 222a-222n is configured to output an electrical output 442a-442n for use during high dynamic range image capture mode, and an electrical output on the combined electrical output 446 connected to the switching device 224 for use during a time-of-flight sensing mode.

As further depicted in FIG. 4, the example macropixel 110 includes a mux 444a-444n configured to select the input signal for the flip-flop 440a-440n associated with each SPAD 443a-443n. The mux 444a-444n is configured to select between the electrical output 442a-442n during a high dynamic range input capture mode and the output of a neighboring flip-flop 440a-440n during a time-of-flight sensing mode. As further depicted in FIG. 4, the first mux 444a is configured to receive either the combined electrical output 446 through the switching device 224 or the shift register input 335 from a neighboring macropixel. The output of the final flip-flop 440n is further output further transmitted on the shift register output 336 based on the mode of operation.

As further depicted in FIG. 4, the output of each flip-flop 440a-440n is transmitted to a first input of a NOR logic gate 445a-445n. The second input of the NOR logic gate 445a-445n is configured to receive a memory access signal 448a-448n. The memory access signal 448a-448n is asserted when the data from the corresponding flip-flop 440a-440n is to be written to the corresponding memory word 332a-332n.

As further depicted in FIG. 4, the example macropixel 110 includes a memory device 228 comprising a plurality of memory words 332a-332m. Further, each memory word 332a-332m includes a plurality of memory bits 447a-447j. As depicted in FIG. 4, each memory bit 447a-447j comprises a six transistor SRAM component.

As further depicted in FIG. 4, each memory word 332a-332n is accessible by read-write data lines 334a-334j. The read-write data lines 334a-334j enable the data from each memory word 332a-332n to be read by an external device configured to interface with the read-write data lines 334a-334j. In addition, the read-write data lines 334a-334j enable the data from each memory word 332a-332n to be written to by an external device configured to interface with the read-write data lines 334a-334j.

Referring now to FIG. 5, the electrical signal flow on an example macropixel 110 configured by the switching device 224 to operate in a high dynamic range image capture mode, is depicted. Thus, as depicted in FIG. 5, the muxes 444a-444n are configured to transmit the electrical output 442a-442n from each of the SPADs 443a-443n to the flip-flops 440a-440n. As such, the shift register of the shift register circuitry 226 is disabled.

As further depicted in FIG. 5, one or more photons 550 are received at the SPAD 443b. In the depicted configuration, the SPADs 443a-443n are charged. Thus, receipt of one or more photons 550 causes the SPAD 443b to discharge and output an electrical output 442b to the mux 444b. When the pixel clock 552 rises, the flip-flop 440b samples the SPAD 443b state as indicated by the electrical output 442b. In the depicted example, a 0 is written into the flip-flop 440b. At the end of the integration period, the memory access signals 448a-448n are asserted. In some embodiments, the memory access signals 448a-448n are asserted one at a time based on a one hot encoding. Because access to the memory word 332b is controlled by a NOR logic gate 445b, the memory word 332b is accessed in an instance in which the memory access signal 448b is low. Thus, in an instance in which the memory access signal 448b is low and the flip-flop 440b output is 0, a digital 1 is transmitted to the memory word 332b, causing the count stored by the memory word 332b to be incremented.

Referring now to FIG. 6, the electrical signal flow on an example macropixel 110 configured by the switching device 224 to operate in a time-of-flight sensing mode, is depicted. In the time-of-flight sensing mode, the shift register of the shift register circuitry 226 is enabled. Thus, as depicted in FIG. 6, the muxes 444a-444n are configured to transmit the output from the neighboring flip-flop 440a-440n to the next flip-flop 440a-440n. In addition, the first mux 444a is configured to receive the combined electrical output 446 passed through the switching device 224.

As depicted in FIG. 6, an illumination source may output light prior to starting the pixel clock 552 on the shift register circuitry 226. As further depicted in FIG. 6, one or more photons 550 are received at the SPAD 443b after the pixel clock 552 is started. In the depicted configuration, the SPADs 443a-443n are charged. Thus, receipt of one or more photons 550 causes the SPAD 443b to discharge and output an electrical output of 0. The electrical output from the mux 444b is received on the combined electrical output 446. The combined electrical output is a wire OR of all the electrical outputs of the SPADs 443a-443n. The shift register mux 660 is configured to select between the output of the switching device 224 and the shift register input 335 based on the configuration of the shift register during the time-of-flight sensing mode. As depicted in FIG. 6, the mux 660 and the mux 44a are configured to transmit the combined electrical output 446 as transmitted by the switching device 224. The digital photon indicator stored by the first flip-flop 440a is shifted through the shift register circuitry at each cycle of the pixel clock 552. For example, to flip-flop 440b and so on until it is received at flip-flop 440n. In an instance in which the digital photon indicator is in flip-flop 440b at the completion of the shifting, the corresponding memory word 332b is incremented when the memory access signal 448b is asserted. Utilizing the shift register circuitry 226 as depicted in FIG. 6, the position of the digital photon indicator in the shift register circuitry 226 indicates the time of photon arrival at one or more of the SPADs 443a-443n. Over time, each memory word 332a-332n represents an n-bin histogram based on various times of arrival of the reflected light output.

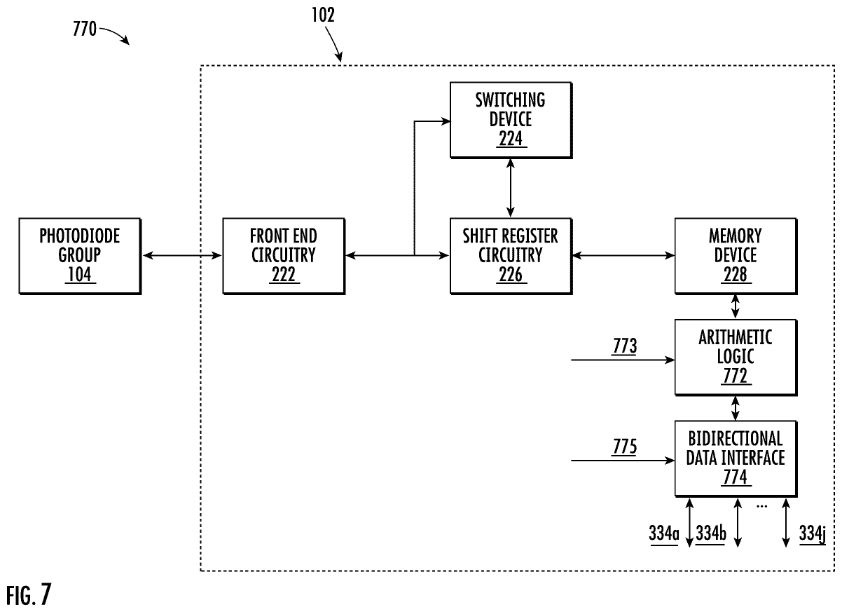

Referring now to FIG. 7, an example block diagram of a macropixel 770 comprising arithmetic logic circuitry 772 and a bidirectional data interface 774 is provided. As depicted in FIG. 7, the example macropixel 770 includes a photodiode group 104 electrically connected to macropixel circuitry 102. The example macropixel circuitry 102 includes front end circuitry 222 electrically connected to the photodiode group 104, shift register circuitry 226, and a switching device 224. The switching device 224 is further electrically connected to the shift register circuitry 226. The memory device 228 is electrically connected to the shift register circuitry 226. As further depicted in FIG. 7, the memory device 228 is electrically connected to arithmetic logic circuitry 772 which is in turn electrically connected to a bidirectional data interface 774. The arithmetic logic is configured to receive arithmetic control signals 773. The bidirectional data interface 774 provides read-write data lines to an external device. In addition, the bidirectional data interface is configured to receive data control signals 775.

As depicted in FIG. 7, the memory device 228 of the macropixel circuitry 102 is electrically connected to arithmetic logic circuitry 772. Arithmetic logic circuitry 772 comprises electrical components configured to perform arithmetic operations on the data in the memory device 228. Arithmetic operations may include increment operations, decrement operations, difference operations, summation operations, compare operations, multiply operations, shift operations, and so on. In some embodiments, the arithmetic logic circuitry 772 may enable the performance of arithmetic operations directly in the memory device 208 included in the macropixel 770. For example, consecutive image frames may be captured in two separate memory words in the memory device 208. In some embodiments, a difference operation may be performed between the first image frame and the second image frame. The resulting difference image may be saved back into a memory word of the memory device 208 or even exported out the bidirectional data interface 774. Thus, arithmetic operations may be performed on captured image data without ever moving the image data off the photodiode-based sensor.

As further depicted in FIG. 7, the arithmetic logic 772 may be configured to receive arithmetic control signals 773. The arithmetic control signals 773 comprise any signals configured to dictate arithmetic operations and/or input/output operations to be performed by the arithmetic logic circuitry 772. For example, arithmetic control signals 773 may include increment signals configured to apply an increment operation to one or more memory words on the memory device 208. Arithmetic control signals 773 may further include input/output operations to configure the arithmetic logic circuitry 772 to read and/or write memory words of the memory device 208.

As further depicted in FIG. 7, the arithmetic logic circuitry 772 is electrically connected to a bidirectional data interface 774. The bidirectional data interface 774 comprises any hardware including routing circuitry configured to enable the performance of data writes and data reads. Data writes comprise writing data to the memory words of the memory device 228. Data reads include reading data from the memory words of the memory device 228. The bidirectional data interface 774 may include read-write data lines 334a-334j corresponding to each memory bit of the memory words comprising the memory device 208. The read-write data lines 334a-334j provide an interface to an external device to provide data and/or extract data from the memory words of the memory device 208.

As further depicted in FIG. 7, the bidirectional data interface 774 is configured to receive one or more data control signals 775. The data control signals 775 may indicate the input/output operations to be performed by the bidirectional data interface 774. For example, a data control signal 775 may indicate whether a read or write operation is to be executed.

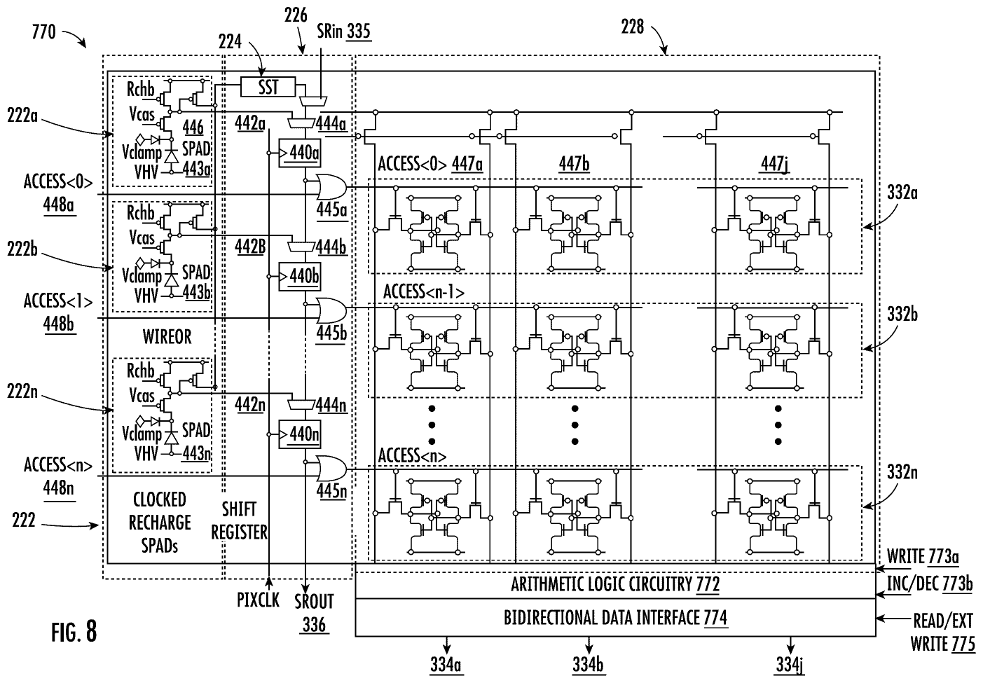

Referring now to FIG. 8, an example embodiment of a macropixel 770 comprising arithmetic logic circuitry 772 and a bidirectional data interface 774 is provided.

As depicted in FIG. 8, the arithmetic logic circuitry 772 is configured to interface with the bitlines of each memory bit 447a-447j of the memory words 332a-332n of the memory device 228. Interfacing the with the bitlines of each memory bit 447a-447j enables arithmetic operations to be performed on image data contained in the memory device 228 without removing any image data from the macropixel 770. As further depicted in FIG. 8, arithmetic control signals, such as a write signal 773a and increment/decrement signal 773b may be received by the arithmetic logic circuitry 772. Such control signals enable control over the arithmetic operation and the input/output operation performed by the arithmetic logic circuitry 772.

As further depicted in FIG. 8, the bidirectional data interface 774 is configured to interface with the bitlines of each memory bit 447a-447j and with the arithmetic logic circuitry 772. The bidirectional data interface 774 provides a conductive path to/from the memory words 332a-332n of the memory device 228 from/to an external device or module, through the read-write data lines 334a-334j. The input/output operations executed by the bidirectional data interface 774 may be controlled by the data control signal 775 received at the bidirectional data interface 774.

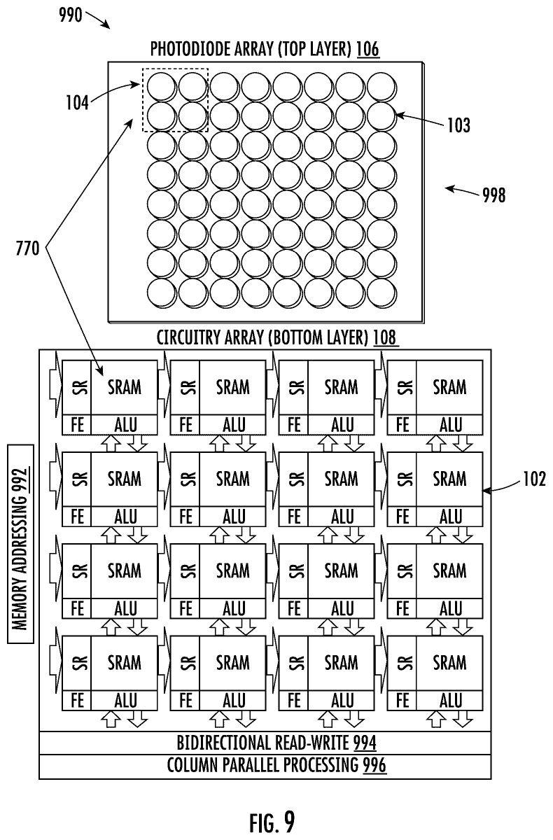

Referring now to FIG. 9, an example photodiode-based sensor 990 is provided. As depicted in FIG. 9, the example photodiode-based sensor 990 includes two layers, a top layer 106 comprising a photodiode array and a bottom layer 108 comprising a circuitry array. The photodiode array includes an array of photodiodes 103 with a plurality of adjacent photodiodes 103 grouped in a photodiode group 104. The circuitry array includes macropixel circuitry 102 for an associated photodiode group 104. The photodiode group 104 on the top layer 106 and corresponding macropixel circuitry 102 on the bottom layer 108 together comprise a macropixel 770. By stacking the photodiode group 104 on top of the associated macropixel circuitry 102, the macropixel 770 and thus photodiode-based sensor 990 occupy less area. A plurality of macropixels 770 are arranged in a two-dimensional array to form a macropixel array 998. As further depicted in FIG. 9, the circuitry array on the bottom layer 108 includes peripheral components configured to interface with the array of macropixel circuitry 102. The peripheral components include memory addressing circuitry 992, bidirectional read-write circuitry 994, and column parallel processing circuitry 996.

As depicted in FIG. 9, the example photodiode-based sensor 990 includes memory addressing circuitry 992. Memory addressing circuitry 992 comprises any circuitry including hardware and/or software configured to coordinate access to each memory word of each memory device in the macropixel array 998. For example, the memory addressing circuitry 992 may coordinate writes to the memory words of the memory device (SRAM) of each macropixel circuitry 102 based on the image capture mode. In a high dynamic range image capture mode, the photodiodes 103 of a macropixel 770 may be pre-charged previous to an integration period. At the conclusion of the integration period, the state of the photodiodes 103 is written into an associated register device (e.g., flip-flops 440a-440n depicted in FIG. 4-FIG. 6). The memory addressing circuitry 992 may then coordinate the write of the state contained in the register devices to the memory words of the associated memory device. For example, the memory addressing circuitry 992 may toggle the memory access signals (e.g., memory access signals 448a-448n as depicted in FIG. 4-FIG. 6) one by one to write the stored values to the corresponding memory word.

In a time-of-flight sensing mode, the memory addressing circuitry 992 may disable memory addressing during the time-of-flight acquisition. For example, the photodiodes 103 of a macropixel 770 may be pre-charged previous to an acquisition period. A light pulse may then be emitted and the photodiodes 103 released from pre-charge. During the acquisition period, the indication of captured photons (e.g., a logic 0) is transmitted through the shift register circuitry (SR) of the macropixel circuitry 102. Once the acquisition period is complete, the memory addressing circuitry 992 may then coordinate the write of the state contained in the register devices to the memory words of the associated memory device, for example, by toggling the memory access signals (e.g., memory access signals 448a-448n as depicted in FIG. 4-FIG. 6) one by one to write the stored values to the corresponding memory word.

As further depicted in FIG. 9, the photodiode-based sensor 990 includes bidirectional read-write circuitry 994. Bidirectional read-write circuitry 994 comprises any circuitry, including routing circuitry, configured to enable data reads and data writes to each memory word of the memory devices (SRAM) comprising the macropixels 770 of the macropixel array 998. In some embodiments, the bidirectional read-write circuitry 994 may interface with the bidirectional data interface (e.g., bidirectional data interface 774 as depicted in FIG. 7) of each macropixel 770 to enable read/write access to each memory word of each macropixel 770.

As further depicted in FIG. 9, the example photodiode-based sensor 990 includes column parallel processing circuitry 996. Column parallel processing circuitry 996 comprises any circuitry including hardware and/or software on the photodiode-based sensor 990 configured to manage processing operations performed on the photodiode-based sensor 990. For example, the column parallel processing circuitry 996 may utilize the bidirectional read-write circuitry 994 to coordinate image processing operations, machine learning operations based on a machine learning model, and other similar data processing operations without removing the data from the photodiode-based sensor 990. Image processing operations may include peak finding operations, centroiding operations, edge detection operations, movement operations, and other similar operations. In one non-limiting example, the column parallel processing circuitry 996 may perform edge detection operations by comparing nearby memory word values (e.g., pixel values) and determining if a gradient exceeds a certain threshold gradient. The bidirectional read-write circuitry 994 may then write the edge detection results to another memory word, the same memory word, or even output the results of the edge detection. The column parallel processing may similarly perform other image processing operations.

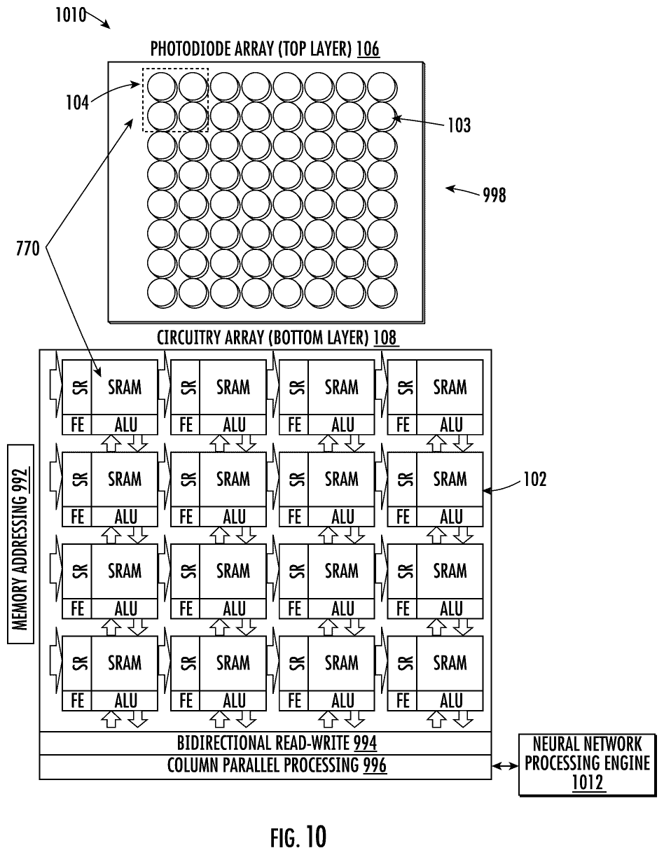

In some embodiments, the column parallel processing circuitry 996 may pre-load one or more memory words with various values to aid the performance of various data processing operations. For example, the column parallel processing circuitry 996 may pre-load base image values, weights, filter values, masks, and so on. The column parallel processing circuitry 996 may further be configured to perform machine learning operations on the photodiode-based sensor 990, dictated by a machine learning model, without removing data from the photodiode-based sensor 990. Machine learning operations are further discussed in relation to FIG. 10.

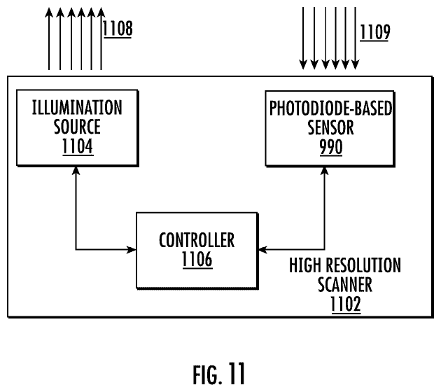

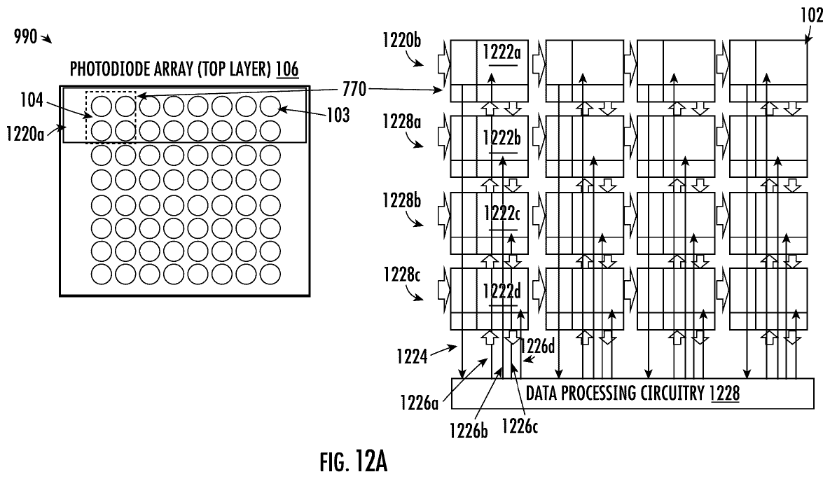

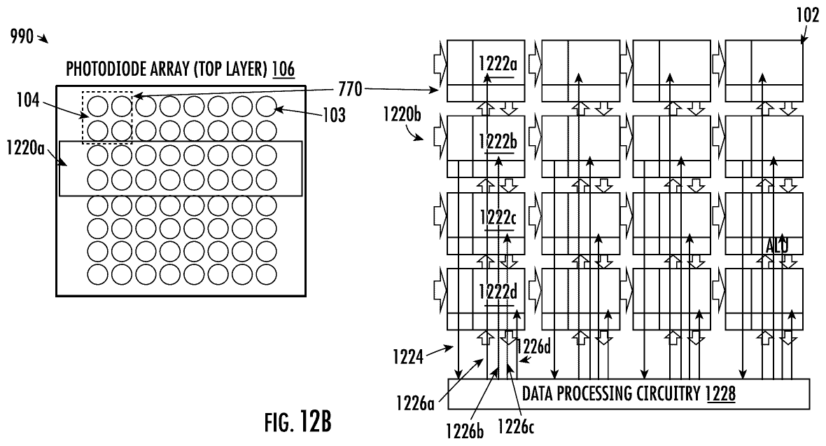

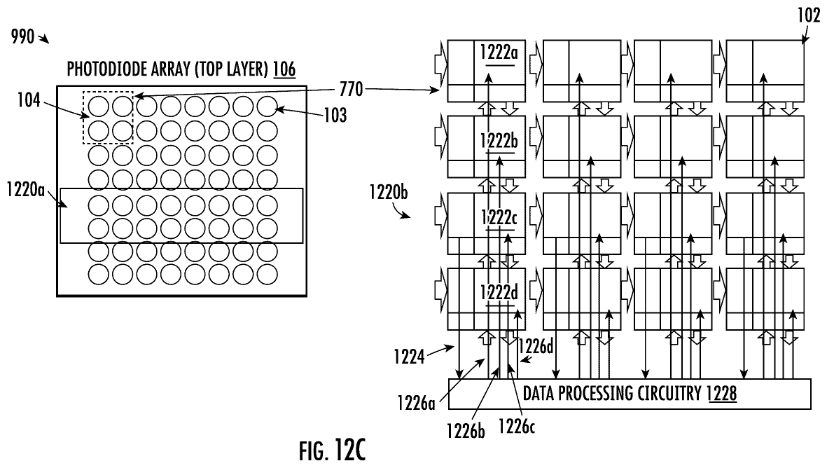

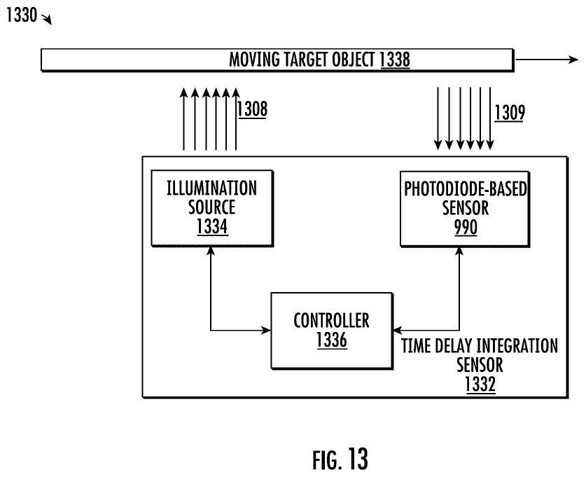

In some embodiments, the column parallel processing circuitry 996 may be configured to coordinate the transfer of data between macropixel 770 memory devices of the macropixel array 998. For example, the bidirectional read-write circuitry 994 may coordinate the transfer data between macropixels 770 within the macropixel array 998. Transferring data between macropixels 770 may enable applications in which light intensity data received at a photodiode group 104 may be written to the memory device (e.g., SRAM) of another macropixel 770. Such functionality may enable certain applications, such as the high resolution scanner operation described in relation to FIG. 11-FIG. 12C, and the time delay integration sensor described in relation to FIG. 13-FIG. 15.

Referring now to FIG. 10, a block diagram of an example photodiode-based sensor 1010 including a neural network processing engine 1012 is provided. As depicted in FIG. 10, the example photodiode-based sensor 1010 includes two layers, a top layer 106 comprising a photodiode array and a bottom layer 108 comprising a circuitry array. The photodiode array includes an array of photodiodes 103 with a plurality of adjacent photodiodes 103 grouped in a photodiode group 104. The circuitry array includes macropixel circuitry 102 for an associated photodiode group 104. The photodiode group 104 on the top layer 106 and corresponding macropixel circuitry 102 on the bottom layer 108 together comprise a macropixel 770. By stacking the photodiode group 104 on top of the associated macropixel circuitry 102, the macropixel 770 and thus photodiode-based sensor 1010 occupy less area. A plurality of macropixels 770 are arranged in a two-dimensional array to form a macropixel array 998. The circuitry array on the bottom layer 108 includes peripheral components configured to interface with the array of macropixel circuitry 102. The peripheral components include memory addressing circuitry 992, bidirectional read-write circuitry 994, and column parallel processing circuitry 996. As further depicted in FIG. 10, the column parallel processing circuitry 996 interfaces with a neural network processing engine 1012.

A neural network processing engine 1012 is any circuitry including hardware and/or software configured to enable the execution of one or more machine learning operations related to a neural network configured by a machine learning model. In some embodiments, the neural network processing engine 1012 may be implemented on the column parallel processing circuitry 996.

A neural network may be configured by a machine learning model to execute various operations related to captured image data in order to generate one or more classifications related to the captured image data. Classifications may include identification of objects and activities, identification of individuals, and so on. Neural network operations may include convolution algorithms, pooling algorithms, classifiers, and so on. The neural network processing engine may generate and/or provide pre-computed values that may be loaded into the memory words of the various macropixel 770 memory devices to facilitate the execution of neural network operations. For example, a neural network operation may include applying weights to each pixel value in captured imaged data. The neural network processing engine 1012 in coordination with the column parallel processing circuitry 996 and the bidirectional read-write circuitry 994 may write the pixel weights to the corresponding memory word in the macropixel array 998. Thus, when a pixel value is captured during the integration phase, the column parallel processing circuitry 996 may apply (e.g., multiply) the corresponding weight value stored at the macropixel array 998 location to the captured pixel value. Thus, the neural network operation may be performed without ever removing the image data from the photodiode-based sensor 1010.

In some embodiments, multiple neural network operations may be performed on the captured image data before extracting the image data from the photodiode-based sensor 1010. For example, a classification may be determined at the photodiode-based sensor 1010. Thus, a classification may be extracted from the image data without ever transmitting the image data off the photodiode-based sensor. Such operation may increase the security of a classification device. For example, in a face detection device, the image data including a person's face may never have to be extracted from the photodiode-based sensor 1010. The photodiode-based sensor 1010 may simply output a positive or negative identification instead of the imagery data, preventing the transmission of imagery data containing individual faces. Similar operations may be performed in other neural network classification algorithms. In addition to increased security and privacy, the neural network processing engine 1012 implemented on the photodiode-based sensor 1010 may reduce network traffic and power consumption.

Referring now to FIG. 11, a block diagram of an example high resolution scanner 1102 is provided. As depicted in FIG. 11, the example high resolution scanner 1102 includes a controller 1106 electrically connected to an illumination source 1104 and electrically connected to a photodiode-based sensor 990 in accordance with one or more example embodiments described herein. As further depicted in FIG. 11, the illumination source 1104 is configured to generate a light output 1108. The photodiode-based sensor 990 is positioned to receive the light output 1108 reflected off a target object and returned as reflected light 1109.

As depicted in FIG. 11, the example high resolution scanner 1102 includes an illumination source 1104. An illumination source 1104 comprises any light source or array of light sources comprising a semiconductor, diode, or other photon emitting structure configured to generate optical output, such as laser light. An illumination source 1104 may be configured to generate light output at a specific wavelength or spectrum of wavelengths. In some embodiments, the illumination source 1104 may comprise one or more vertical cavity surface emitting lasers (VCSELs). As depicted in FIG. 12A - FIG. 12C, the illumination source 1104 of a high resolution scanner 1102 is configured to generate a band of light output (e.g., light blade) such that only a portion of the photodiodes of a photodiode-based sensor 990 are active while the illumination source 1104 is illuminated.

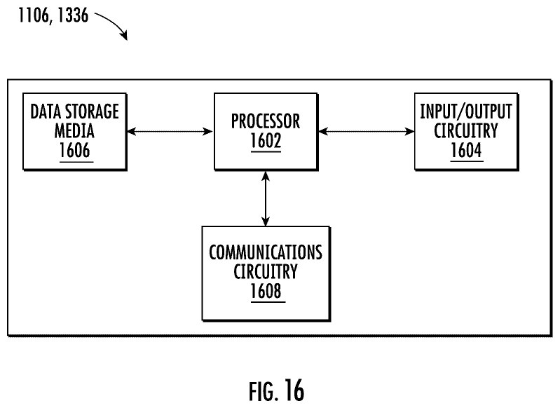

As further depicted in FIG. 11, the example high resolution scanner 1102 includes a controller 1106. A controller 1106 comprises one or more computing devices electrically coupled to the illumination source 1104 and the photodiode-based sensor 990 and configured to coordinate the generation of light output at the illumination source 1104. The controller 1106 may further extract image data from the photodiode-based sensor 990. An example block diagram of a controller 1106 architecture is described further in relation to FIG. 16.

Referring now to FIG. 12A-FIG. 12C, an example process for generating a high resolution image on a high resolution scanner (e.g., high resolution scanner 1102) comprising a photodiode-based sensor 990 is provided.

As depicted in FIG. 12A, the example photodiode-based sensor 990 includes a plurality of photodiodes 103 arranged in a two-dimensional array on a top layer 106 of the photodiode-based sensor 990. A plurality of adjacent photodiodes 103 are arranged in a photodiode group 104. Each photodiode group 104 is associated with macropixel circuitry 102 positioned on a layer under the top layer 106. The photodiode group 104 and associated macropixel circuitry 102 comprise a macropixel 770. During operation of a high resolution scanner, light output is scanned across a surface such that only an active portion 1220a of the two-dimensional array of photodiodes are activated in a given time period. In an instance in which an active portion 1220a of the photodiode array is exposed to reflected light the memory devices (SRAM) in the corresponding row of active macropixels 1220b are utilized, while the memory devices (SRAM) of the inactive portions of the macropixel circuitry 102 array are unutilized.

As depicted in FIG. 12A, to increase efficiency and resolution, a macropixel 770 in the row of active macropixels 1220b of the photodiode-based sensor 990 may utilize unutilized memory devices of macropixels 770 outside of the row of active macropixels 1220b, for example, unutilized rows 1228a, 1228b, 1228c as depicted in FIG. 12A. For example, in an instance in which light is received at a macropixel in the row of active macropixels 1220b, registered values may be written out to data processing circuitry 1228. The data processing circuitry 1228 may then utilize other memory devices in the array of macropixel circuitries 102 to store one or more values related to the pixel intensity of a photodiode 103 in the active portion 1220a of the two-dimensional photodiode array.

For example, as depicted in FIG. 12A, an active macropixel in the row of active macropixels 1220b may transmit light intensity output data on the data out line 1224. During a first integration period, the data processing circuitry 1228 may write the light intensity output data to a first memory device 1222a in the column of the active macropixel, as indicated by the first data write 1226a. During a second integration period, the data processing circuitry 1228 may write the light intensity output data to a second memory device 1222b in the column of the active macropixel, as indicated by the second data write 1226b. During a third integration period, the data processing circuitry 1228 may write the light intensity output data to a third memory device 1222c in the column of the active macropixel, as indicated by the third data write 1226c. During a fourth integration period, the data processing circuitry 1228 may write the light intensity output data to a fourth memory device 1222d in the column of the active macropixel, as indicated by the fourth data write 1226d. By utilizing the inactive memory devices of inactive macropixels to store light intensity output data for the macropixels in the active macropixels 1220b of the photodiode-based sensor 990, the resolution of the captured image data may be substantially increased.

Referring now to FIG. 12B, the light output from the illumination device has progressed to a second active portion 1220a and a second row of active macropixels 1220b of the photodiode-based sensor 990. As depicted in FIG. 12B, an active macropixel in the row of active macropixels 1220b may transmit light intensity output data on the data out line 1224. During a first integration period, the data processing circuitry 1228 may write the light intensity output data to the first memory device 1222a in the column of the active macropixels 1220b, as indicated by the first data write 1226a. During a second integration period, the data processing circuitry 1228 may write the light intensity output data to a second memory device 1222b in the column of the active macropixel, as indicated by the second data write 1226b. During a third integration period, the data processing circuitry 1228 may write the light intensity output data to a third memory device 1222c in the column of the active macropixel, as indicated by the third data write 1226c. During a fourth integration period, the data processing circuitry 1228 may write the light intensity output data to a fourth memory device 1222d in the column of the active macropixel 770, as indicated by the fourth data write 1226d.

Referring now to FIG. 12C, the light output from the illumination device has progressed to a third active portion 1220a and a third row of active macropixels 1220b of the photodiode-based sensor 990. As depicted in FIG. 12C, an active macropixel in the row of active macropixels 1220b may transmit light intensity output data on the data out line 1224. During a first integration period, the data processing circuitry 1228 may write the light intensity output data to the first memory device 1222a in the column of the active macropixel, as indicated by the first data write 1226a. During a second integration period, the data processing circuitry 1228 may write the light intensity output data to a second memory device 1222b in the column of the active macropixel, as indicated by the second data write 1226b. During a third integration period, the data processing circuitry 1228 may write the light intensity output data to a third memory device 1222c in the column of the active macropixel, as indicated by the third data write 1226c. During a fourth integration period, the data processing circuitry 1228 may write the light intensity output data to a fourth memory device 1222d in the column of the active macropixel, as indicated by the fourth data write 1226d.

Referring now to FIG. 13, a block diagram of an example time delay integration sensor 1332 is provided. As depicted in FIG. 13, the example time delay integration sensor 1332 includes a controller 1336 electrically connected to an illumination source 1334 and electrically connected to a photodiode-based sensor 990 in accordance with one or more example embodiments described herein. As further depicted in FIG. 13, the illumination source 1334 is configured to generate a light output 1308 directed at a moving target object 1338. The photodiode-based sensor 990 is positioned to receive reflected light 1309 off the moving target object 1338. A time delay integration sensor 1332 may be a specific embodiment of a high resolution scanner (e.g., high resolution scanner 1102).

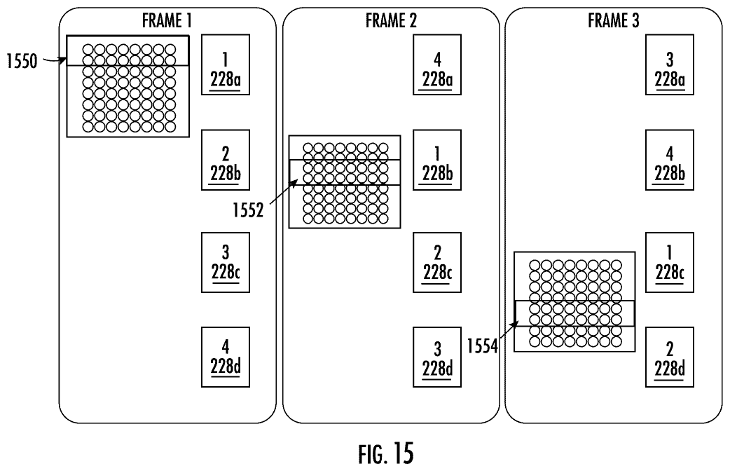

As depicted in FIG. 13, the example time delay integration sensor 1332 is positioned to transmit a narrow light output 1308 directed at a moving target object 1338. The moving target object 1338 may be any object passed proximate the time delay integration sensor 1332 for which the time delay integrations sensor 1332 is configured to capture high resolution image data. For example, a target object may be a mail parcel, a bank note, or other similar object moving at a high rate of speed. In some embodiments, the time delay integration sensor 1332 may be used to rapidly scan the earth from a distant satellite. As further depicted in relation to FIG. 15, in some embodiments, a portion of the photodiodes comprising the photodiode-based sensor 990 may be selectively activated to track the motion of the moving target object 1338 as it moves past the time delay integration sensor 1332.

As depicted in FIG. 13, the example time delay integration sensor 1332 includes an illumination source 1334. An illumination source 1334 comprises any light source or array of light sources comprising a semiconductor, diode, or other photon emitting structure configured to generate optical output, such as laser light. An illumination source 1334 may be configured to generate light output at a specific wavelength or spectrum of wavelengths. In some embodiments, the illumination source 1334 may comprise one or more vertical cavity surface emitting lasers (VCSELs). As depicted in FIG. 15, the illumination source 1334 of a time delay integration sensor 1332 is configured to generate a narrow band of light output 1308 such that only a portion of the photodiodes of a photodiode-based sensor 990 are active while the illumination source 1334 is illuminated.

As further depicted in FIG. 13, the example time delay integration sensor 1332 includes a controller 1336. A controller 1336 comprises one or more computing devices electrically coupled to the illumination source 1334 and the photodiode-based sensor 990 and configured to coordinate the generation of light output at the illumination source 1334 and the activation of photodiodes on the photodiode-based sensor 990. The controller 1336 may further extract image data from the photodiode-based sensor 990. An example block diagram of a controller 1336 architecture is described further in relation to FIG. 16.

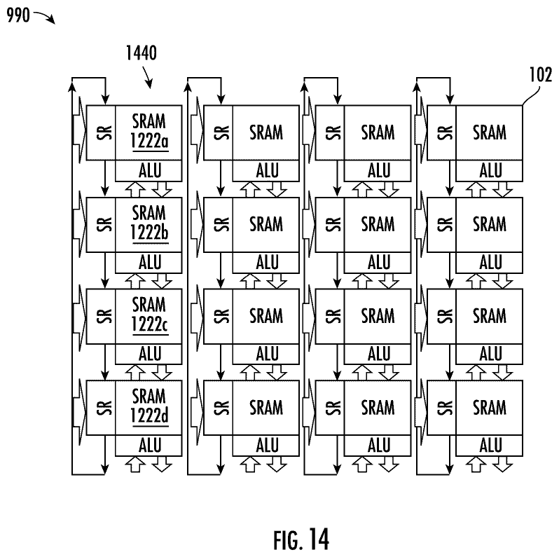

Referring now to FIG. 14, an example two-dimensional array of macropixel circuitries 102 on a photodiode-based sensor 990 is provided. As depicted in FIG. 14, the various macropixel circuitries 102 of the two-dimensional array of macropixel circuitries 102 is configured in a circular buffer configuration. In a circular buffer configuration, the shift register circuitry (e.g., shift register circuitry 226), including the shift register input and the shift register output (e.g., shift register input 335 and shift register output 336) of the macropixel circuitry 102 are utilized to transmit light intensity data between neighboring macropixel circuitries 102 in a macropixel column 1440. As depicted in FIG. 14, in an instance in which the pixel clock of the shift register circuitry is enabled, light intensity data is shifted between the macropixel circuitry 102 of neighboring macropixel circuitry 102 in the macropixel column 1440. For example, light intensity data is shifted from the first memory 1222a to the second memory device 1222b, from the second memory device 1222b to the third memory device 1222c, and so on. In addition, light intensity data of the last macropixel 1222d in the macropixel column 1440 is written back to the first memory device 1222a to create a circular buffer. In some embodiments, the circular buffer configuration may be enabled by data processing circuitry, such as data processing circuitry 1228 described in relation to FIG. 12A-FIG. 12C.

As depicted in FIG. 15, a circular buffer configuration, as depicted in relation to FIG. 14, enables the writing of light intensity data to the memory devices of the photodiode-based sensor 990 to compensate for the motion of the moving target object as it passes by the photodiode-based sensor 990.

As depicted in FIG. 15, in an example Frame 1, a portion of the moving target object is positioned proximate a first set of macropixels 1550. At example Frame 2, the same portion of the moving target object is positioned proximate a second set of macropixels 1552. At example Frame 3, the same portion of the moving object is positioned proximate a third set of macropixels 1554. A circular buffer or similar data shifting mechanism is utilized to shift the light intensity data received at the set of macropixels 1550, 1552, 1554, to compensate for the motion of the moving target object.

For example, at Frame 1, a portion of the moving target object may be proximate the set of macropixels 1550 and the light intensity data corresponding to portion of the moving object may be written to the memory devices 228a associated with the set of macropixels 1550. At Frame 2, the same portion of the moving target object may be proximate the set of macropixels 1552, however, a data shifting mechanism may be executed to compensate for the motion of the moving target object such that the light intensity data received at the set of macropixels 1552 is written back to the memory devices 228a. Similarly, at Frame 3, the same portion of the moving target object may be proximate the set of macropixels 1554, however, the data shifting mechanism may be executed to compensate for the motion of the moving target object such that the light intensity data received at the set of macropixels 1552 is written back to the memory devices 228a. Thus, once the moving target object has past by the photodiode-based sensor, all light intensity corresponding to the same portion of the moving target object is stored at memory device 228a, enabling extraction of a high resolution image of the moving target object even when moving at high speeds.

Referring now to FIG. 16, FIG. 16 illustrates an example controller 1106, 1336 in accordance with at least some example embodiments of the present disclosure. The controller 1106, 1336 includes processor 1602, input/output circuitry 1604, data storage media 1606, and communications circuitry 1608. In some embodiments, the controller 1106, 1336 is configured, using one or more of the sets of circuitry 1602, 1604, 1606, and/or 1608, to execute and perform the operations described herein.

Although components are described with respect to functional limitations, it should be understood that the particular implementations necessarily include the use of particular computing hardware. It should also be understood that in some embodiments certain of the components described herein include similar or common hardware. For example, two sets of circuitry may both leverage use of the same processor(s), network interface(s), storage medium(s), and/or the like, to perform their associated functions, such that duplicate hardware is not required for each set of circuitry. The user of the term “circuitry” as used herein with respect to components of the apparatuses described herein should therefore be understood to include particular hardware configured to perform the functions associated with the particular circuitry as described herein.

Particularly, the term “circuitry” should be understood broadly to include hardware and, in some embodiments, software for configuring the hardware. For example, in some embodiments, “circuitry” includes processing circuitry, storage media, network interfaces, input/output devices, and/or the like. Alternatively, or additionally, in some embodiments, other elements of the controller 1106, 1336 provide or supplement the functionality of other particular sets of circuitry. For example, the processor 1602 in some embodiments provides processing functionality to any of the sets of circuitry, the data storage media 1606 provides storage functionality to any of the sets of circuitry, the communications circuitry 1608 provides network interface functionality to any of the sets of circuitry, and/or the like.

In some embodiments, the processor 1602 (and/or co-processor or any other processing circuitry assisting or otherwise associated with the processor) is/are in communication with the data storage media 1606 via a bus for passing information among components of the controller 1106, 1336. In some embodiments, for example, the data storage media 1606 is non-transitory and may include, for example, one or more volatile and/or non-volatile memories. In other words, for example, the data storage media 1606 in some embodiments includes or embodies an electronic storage device (e.g., a computer readable storage medium). In some embodiments, the data storage media 1606 is configured to store information, data, content, applications, instructions, or the like, for enabling the controller 1106, 1336 to carry out various functions in accordance with example embodiments of the present disclosure.

The processor 1602 may be embodied in a number of different ways. For example, in some example embodiments, the processor 1602 includes one or more processing devices configured to perform independently. Additionally, or alternatively, in some embodiments, the processor 1602 includes one or more processor(s) configured in tandem via a bus to enable independent execution of instructions, pipelining, and/or multithreading. The use of the terms “processor” and “processing circuitry” should be understood to include a single core processor, a multi-core processor, multiple processors internal to the controller 1106, 1336, and/or one or more remote or “cloud” processor(s) external to the controller 1106, 1336.

In an example embodiment, the processor 1602 is configured to execute instructions stored in the data storage media 1606 or otherwise accessible to the processor. Alternatively, or additionally, the processor 1602 in some embodiments is configured to execute hard-coded functionality. As such, whether configured by hardware or software methods, or by a combination thereof, the processor 1602 represents an entity (e.g., physically embodied in circuitry) capable of performing operations according to an embodiment of the present disclosure while configured accordingly. Alternatively, or additionally, as another example in some example embodiments, when the processor 1602 is embodied as an executor of software instructions, the instructions specifically configure the processor 1602 to perform the algorithms embodied in the specific operations described herein when such instructions are executed.

In some embodiments, the controller 1106, 1336 includes input/output circuitry 1604 that provides output to the user and, in some embodiments, to receive an indication of a user input. In some embodiments, the input/output circuitry 1604 is in communication with the processor 1602 to provide such functionality. The input/output circuitry 1604 may comprise one or more user interface(s) (e.g., user interface) and in some embodiments includes a display that comprises the interface(s) rendered as a web user interface, an application user interface, a user device, a backend system, or the like. The processor 1602 and/or input/output circuitry 1604 comprising the processor may be configured to control one or more functions of one or more user interface elements through computer program instructions (e.g., software and/or firmware) stored on a memory accessible to the processor (e.g., data storage media 1606, and/or the like). In some embodiments, the input/output circuitry 1604 includes or utilizes a user-facing application to provide input/output functionality to a client device and/or other display associated with a user.

In some embodiments, the controller 1106, 1336 includes communications circuitry 1608. The communications circuitry 1608 includes any means such as a device or circuitry embodied in either hardware or a combination of hardware and software that is configured to receive and/or transmit data from/to a network and/or any other device, circuitry, or module in communication with the controller 1106, 1336. In this regard, the communications circuitry 1608 includes, for example in some embodiments, a network interface for enabling communications with a wired or wireless communications network. Additionally, or alternatively in some embodiments, the communications circuitry 1608 includes one or more network interface card(s), antenna(s), bus(es), switch(es), router(s), modem(s), and supporting hardware, firmware, and/or software, or any other device suitable for enabling communications via one or more communications network(s). Additionally, or alternatively, the communications circuitry 1608 includes circuitry for interacting with the antenna(s) and/or other hardware or software to cause transmission of signals via the antenna(s) or to handle receipt of signals received via the antenna(s). In some embodiments, the communications circuitry 1608 enables transmission to and/or receipt of data from a client device in communication with the controller 1106, 1336.

Additionally, or alternatively, in some embodiments, one or more of the sets of circuitry 1602-1608 are combinable. Additionally, or alternatively, in some embodiments, one or more of the sets of circuitry perform some or all of the functionality described associated with another component. For example, in some embodiments, one or more sets of circuitry 1602-1608 are combined into a single module embodied in hardware, software, firmware, and/or a combination thereof. Similarly, in some embodiments, one or more of the sets of circuitry is/are combined such that the processor 1602 performs one or more of the operations described above with respect to each of these circuitry individually.

While this detailed description has set forth some embodiments of the present invention, the appended claims cover other embodiments of the present invention which differ from the described embodiments according to various modifications and improvements. For example, one skilled in the art may recognize that such principles may be applied to any electronic device that utilizes a light detecting sensor, for example, a camera image sensor, a time-of-flight image sensor, an ambient light sensor, a proximity sensor, various scanning devices, and so on.

Within the appended claims, unless the specific term “means for” or “step for” is used within a given claim, it is not intended that the claim be interpreted under 35 U.S. C. 112, paragraph 6.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. A macropixel comprising:
a plurality of photodiodes;
a plurality of memory devices, comprising at least one memory device for each photodiode in the plurality of photodiodes; and
switching circuitry configured to switch between a high dynamic range image capture mode and a time-of-flight sensing mode;
wherein during the high dynamic range image capture mode, a corresponding memory device of the plurality of memory devices is configured to determine an individual intensity of light received at a particular photodiode of the plurality of photodiodes, and
wherein during the time-of-flight sensing mode, each memory device of the plurality of memory devices is configured to determine a group intensity of light received at the plurality of photodiodes during a time period, wherein each memory device is associated with a different time period.

2. The macropixel of claim 1, further comprising front end circuitry for each photodiode in the plurality of photodiodes, the front end circuitry comprising:
a flip-flop configured to receive a pixel clock and an electrical output of a corresponding photodiode in the plurality of photodiodes corresponding to the individual intensity of light received at the photodiode,
wherein the flip-flop is configured to capture a digital photon indicator based on the electrical output at a cycle of the pixel clock, and
wherein the digital photon indicator indicates reception of one or more photons at the photodiode.

3. The macropixel of claim 2, further comprising shift register circuitry configured to transmit the digital photon indicator between each flip-flop of the front end circuitry based on the pixel clock.

4. The macropixel of claim 3, the front end circuitry further comprising a mux configured to select between the electrical output of the corresponding photodiode and the digital photon indicator from a neighboring flip-flop.

5. (canceled)

6. (canceled)

7. The macropixel of claim 4, wherein the switching circuitry is configured to receive the electrical output from each photodiode in the plurality of photodiodes to generate a combined electrical output, and wherein the switching circuitry is configured to transmit the combined electrical output to a first flip-flop in the plurality of flip-flops, wherein the first flip-flop is included in the shift register circuitry.

8. (canceled)

9. (canceled)

10. The macropixel of claim 1, wherein each memory device of the plurality of memory devices comprises static random access memory (SRAM) defined by one or more SRAM bits.

11. (canceled)

12. (canceled)

13. The macropixel of claim 1, further comprising two or more memory devices for each photodiode, wherein a first memory device stores a first intensity of light during a first frame and a second memory device stores a second intensity of light during a second frame.

14. (canceled)

15. The macropixel of claim 1, comprising:
a top layer comprising the plurality of photodiodes; and
a bottom layer comprising the plurality of memory devices and the switching circuitry.

16. The macropixel of claim 1, further comprising a bidirectional data interface enabling data writes to the plurality of memory devices and data reads from the plurality of memory devices.

17. The macropixel of claim 16, further comprising arithmetic logic circuitry configured to perform arithmetic operations in combination with data writes and data reads.

18. An image sensor comprising a plurality of macropixels arranged in a two-dimensional macropixel array comprising rows and columns, each macropixel comprising:
a plurality of photodiodes;
a plurality of memory devices, comprising at least one memory device for each photodiode in the plurality of photodiodes;
switching circuitry configured to switch between a high dynamic range image capture mode and a time-of-flight sensing mode; and
a bidirectional data interface enabling data writes to the plurality of memory devices and data reads from the plurality of memory devices;
wherein during the high dynamic range image capture mode, a corresponding memory device of the plurality of memory devices is configured to determine an intensity of light received at a particular photodiode of the plurality of photodiodes, and
wherein during the time-of-flight sensing mode, each memory device of the plurality of memory devices is configured to determine an intensity of light received at the plurality of photodiodes during a time period, wherein each memory device is associated with a different time period.

19. The image sensor of claim 18, further comprising bidirectional read-write circuitry configured to interface with each of the bidirectional data interfaces.

20. The image sensor of claim 19, further comprising column parallel processing circuitry electrically connected to the bidirectional read-write circuitry and configured to perform image processing operations on image data stored in one or more macropixel memory devices.

21. (canceled)

22. The image sensor of claim 18, wherein each macropixel further comprises two or more memory devices for each photodiode.

23. The image sensor of claim 22, further comprising:
a neural network processing engine configured to perform one or more machine learning operations,
wherein a first memory device of the two or more memory devices stores an intensity of light associated with a corresponding photodiode, and a second memory device stores a weight associated with a machine learning model,
wherein the neural network processing engine is configured to apply the weight stored in the second memory device to the intensity of light stored in the first memory device, and wherein the neural network processing engine is further configured to determine a classification based on the machine learning model.

24. (canceled)

25. (canceled)

26. (canceled)

27. The image sensor of claim 23, wherein the classification is transmitted to a device external to the image sensor while intensity data remains on the image sensor.

28. A high resolution scanner comprising:
an illumination source configured to generate a light blade;
an image sensor positioned to receive reflected light from the light blade, the image sensor comprising a plurality of macropixels arranged in a two-dimensional macropixel array comprising rows and columns, each macropixel comprising:
a plurality of photodiodes;
a plurality of memory devices, comprising at least one memory device for each photodiode in the plurality of photodiodes;
switching circuitry configured to switch between a high dynamic range image capture mode and a time-of-flight sensing mode; and
a bidirectional data interface enabling data writes to the plurality of memory devices and data reads from the plurality of memory devices;
wherein during the high dynamic range image capture mode, a corresponding memory device of the plurality of memory devices is configured to determine an intensity of light received at a particular photodiode of the plurality of photodiodes, and
wherein during the time-of-flight sensing mode, each memory device of the plurality of memory devices is configured to determine an intensity of light received at the plurality of photodiodes during a time period, wherein each memory device is associated with a different time period; and
a controller electrically connected to the illumination source and the image sensor.

29. The high resolution scanner of claim 28, the image sensor further comprising bidirectional read-write circuitry configured to interface with each of the bidirectional data interfaces.

30. The high resolution scanner of claim 29, wherein the controller is configured to:
determine one or more active rows of macropixels, wherein the one or more active rows are within a range of the reflected light from the light blade;
receive a first light intensity for an illuminated macropixel in the one or more active rows, wherein the first light intensity corresponds to reflected light received at the plurality of photodiodes comprising the illuminated macropixel during a first time period;
write the first light intensity to a first memory device associated with a first macropixel, the first macropixel in the same column as the illuminated macropixel;
receive a second light intensity for the illuminated macropixel, wherein the second light intensity corresponds to reflected light received at the plurality of photodiodes comprising the illuminated macropixel during a second time period; and
write the second light intensity to a second memory device associated with a second macropixel, the second macropixel in the same column as the illuminated macropixel.

31. The high resolution scanner of claim 30, wherein the first macropixel and the second macropixel are different macropixels.

32.-36. (canceled)

37. The high resolution scanner of claim 28, wherein the illumination source is further configured to transmit the light blade toward a moving object.

38. The high resolution scanner of claim 37, the image sensor further comprising shift register circuitry configured to shift an electrical output from one or more of the plurality of photodiodes to a flip-flop device electrically connected to each memory device of the plurality of memory devices, based on a movement of a moving target object.

39. The high resolution scanner of claim 38, wherein the electrical output is written to a memory device of the plurality of memory devices within each macropixel in a same column of the two-dimensional macropixel array based on a position of the moving object relative to the image sensor.
